(19) United States
(12) Patent Application Publication
(10) Pub. No.: US 2025/0386741 A1
(43) Pub. Date: Dec. 18, 2025

(54) COMPENSATING SPATIALLY-DEPENDENT CIRCUIT FABRICATION NON-UNIFORMITIES

(71) Applicant: Google LLC, Mountain View, CA (US)

(72) Inventors: Sean David Harrington, Santa Barbara, CA (US); Anthony Edward Megrant, Goleta, CA (US); Brian James Burkett, Santa Barbara, CA (US); Andrew Dunsworth, Goleta, CA (US)

(21) Appl. No.: 18/743,520

(22) Filed: Jun. 14, 2024

(51) Int. Cl. H10N 60/01; G03F 1/70; G03F 7/00; H10N 60/12

(52) U.S. Cl. CPC H10N 60/0912; G03F 1/70; G03F 7/705; G03F 7/70625; H10N 60/12

(57) ABSTRACT

A method for fabricating a circuit element on a substrate by a fabrication system including obtaining a write file including information characterizing features arranged at multiple locations with respect to a surface of the substrate, each feature having a first end and a second end defined along a first feature direction of the feature, generating, for each of the multiple locations and using a geometric relationship defined between a process vector of a process source of the fabrication system and the location of the feature on the substrate, a rotational value, and modifying the write file to generate a modified write file including for at least one feature of the multiple features at a respective location with respect to the surface of the substrate, rotating the first feature direction of the feature about an axis normal to the surface of the substrate by the rotation value.

### TECHNICAL FIELD

The present disclosure relates to compensating spatially-dependent non-uniformities in circuit elements, such as quantum computing circuit elements.

### BACKGROUND

Quantum computing is a relatively new computing method that takes advantage of quantum effects, such as superposition of basis states and entanglement to perform certain computations more efficiently than a classical digital computer. In contrast to a digital computer, which stores and manipulates information in the form of bits (e.g., a “1” or “0”), quantum computing systems can manipulate information using qubits. A qubit can refer to a quantum device that enables the superposition of multiple states (e.g., data in both the “0” and “1” state) and/or to the superposition of data, itself, in the multiple states. In accordance with conventional terminology, the superposition of a “0” and “1” state in a quantum system may be represented, e.g., as α|0>+β|1>. The “0” and “1” states of a digital computer are analogous to the |0> and |1> basis states, respectively of a qubit. The value |α|² represents the probability that a qubit is in |0> state, whereas the value |β|² represents the probability that a qubit is in the |1> basis state.

### SUMMARY

In general, in one aspect, the subject matter of the present disclosure may be embodied in methods for fabricating a circuit element on a substrate by a fabrication system including obtaining, by one or more processors, a write file including information characterizing multiple features arranged at multiple locations with respect to a surface of the substrate, each feature having a first end and a second end defined along a first feature direction of the feature, generating, by the one or more processors and for each of the multiple locations and using a geometric relationship defined between a process vector of a process source of the fabrication system and the location of the feature on the substrate, a rotational value, and modifying, by the one or more processors, the write file to generate a modified write file including for at least one feature of the multiple features at a respective location with respect to the surface of the substrate, rotating the first feature direction of the feature about an axis normal to the surface of the substrate by the rotation value.

In some implementations, the write file is a lithography mask write file, and the geometric relationship is defined between a deposition flux vector of a deposition source of the fabrication system and the location of the feature on the substrate.

In some implementations, rotating the first feature direction of the feature about the axis includes rotating the feature about the axis located within the second end such that the first end of the feature is rotated by the rotation value.

In some implementations, generating the rotational value includes obtaining a source-to-substrate distance for a substrate location of the feature on the substrate, determining an angular difference between a component of the process vector and a feature vector along the first feature direction of the feature, the component of the process vector being parallel to the surface of the substrate at the location of the feature on the substrate, and generating, using the angular difference and the source-to-substrate distance for the substrate location of the feature on the substrate, the rotational value.

In some implementations, rotating the feature includes adjusting a position of the second end of the feature to dispose the feature vector to be aligned with the component of the process vector.

In some implementations, generating the rotational value further includes determining, using the source-to-substrate distance, a maximum rotational value for the feature, where a first location of the feature corresponds to a first maximum rotational value and a second, different location of a different feature corresponds to a second, different maximum rotational value.

In some implementations, the mask information characterizes a first feature and a second feature collectively defining contact portions of a Josephson junction, the mask information further characterizing an overlap region including a respective portion of each of a first end of the first feature and a first end of the second feature. The methods further include generating, for the first feature and using a geometric relationship defined between a first deposition flux vector and the first feature at a location of the first feature on the substrate, a first rotational value, generating, for the second feature and using a geometric relationship defined between a second, different deposition flux vector and the second feature at a location of the second feature on the substrate, a second rotational value, modifying the mask write file to generate a modified lithography mask write file including rotating the first and the second features about a respective first end of the first and second features and a respective second end of the first and second feature is rotated by the respective first and second rotational values.

In some implementations, rotating the first and the second features includes maintaining a minimum threshold overlap of the overlap region of the first and the second feature after rotating by the respective first and second rotational values.

In some implementations, rotating the first and the second features includes rotating the first feature about a first rotational direction, rotating the second feature about a second, different rotational direction.

In some implementations, the first and the second features include an angle defined between vectors along respective lengths of the first and the second features, and where rotating the first and second features includes updating the angle between respective vectors defined along each respective length of the first and the second features, where the updated angle includes one of an oblique angle and an acute angle.

In some implementations, the mask write file includes geometric and exposure time instructions for defining a pattern in a mask.

In some implementations, the methods include performing lithography as directed by the modified mask write file.

In some implementations, the circuit element is a quantum computing circuit element, for example, the quantum computing circuit element is a Josephson junction.

In some implementations, methods for fabricating circuit elements include depositing a resist layer onto a substrate and performing lithography on the resist layer as directed by a lithography write file to fabricate a first resist mask. A first resist mask can be developed, and a first deposition of a layer performed through the first resist mask at a first deposition angle. Surface oxidation can be performed on the first deposited layer and a second deposition through the first resist mask can be performed at a second deposition angle. The first resist mask and deposited layers can then be processed to lift-off the first resist mask and excess deposited material to form the circuit element.

In some implementations, fabricating the circuit element includes depositing one or more resist layers onto a substrate, where performing lithography as directed by a lithography mask write file includes performing lithography on the one or more resist layers as directed by the modified lithography write file to fabricate one or more resist masks. The one or more resist masks can be developed and one or more directional fabrication processes, for example deposition or directional etch, can be performed through the one or more resist masks, where the processes include one or more parameters. The one or more resist masks and modified layers can be processed to lift-off or strip the resist masks and excess deposited material to form the circuit element.

In some implementations, fabricating the circuit element includes one or more etching or material removal processes. In some instances, an etching or material removal process can be a directional etching process where a source can have a directional, e.g., localized, characteristic. For example, a process can be reactive ion etching (RIE) or ion milling.

In general, in some aspects, the subject matter of the present disclosure may be embodied in a system including a data processing apparatus, a non-transitory memory storage in data communication with the data processing apparatus which stores instructions executable by the data processing apparatus and that upon execution causes the data processing apparatus to perform operations of the methods.

In some implementations, the modified mask write file characterizes a design pattern for a quantum computing circuit element.

In general, the subject matter of the present disclosure relates to improving critical dimension uniformity of circuit elements formed by directional fabrication processes across a substrate. The directional fabrication processes used in the fabrication of circuit elements can include deposition-based processes, material-removal (etchant)-based processes, or a combination thereof. Directional processes can include one or more process sources where a location of the process source relative to a location of the circuit element during the fabrication process can affect a resultant critical dimension of the circuit element with respect to a target critical dimension. For example, the subject matter of the present disclosure can be applied to a circuit element that is a Josephson junction and to improving Josephson junction resistance uniformity across a substrate.

Improving the critical dimension uniformity may include applying a rotation function to modify at least one feature, e.g., a mask feature as defined by a mask write file, such that the modified feature orientation compensates for a non-uniformity in a fabrication process. At least one feature can be rotated to orient the feature with respect to a process vector of the process source in the fabrication chamber, e.g., to align a critical dimension with respect to the process vector of the process source. For example, at least one mask feature can be rotated to orient the mask feature with respect to a deposition beam flux vector for the source in the deposition chamber, e.g., align the mask feature with the beam flux vector. The at least one modified mask feature may include a feature that defines part of a Josephson junction.

The rotation angle for the mask features across the different locations of the mask can be derived from one or more geometric arguments mapping known process parameters to the non-uniform fabrication process. A geometric argument may be understood to include a geometric relationship between one or more process parameters (e.g., source-to-beam distance) and one or more process conditions (e.g., deposition thickness across a substrate) resulting from the one or more process parameters, e.g., due to orientation of the process source flux with respect to the features of the mask at different locations. Mapping a process parameter to the non-uniform fabrication process therefore establishes a geometric relationship between the one or more process parameters and the one or more process conditions resulting from the one or more process parameters.

In some examples, the circuit element is a Josephson junction, where the junction resistance of the Josephson junction is inversely proportional to the cross-sectional area of the junction. Gradients in the deposition conditions of the junction width and thickness result in variability in the junction resistance for deposited Josephson junctions across a substrate. Compensating for critical-dimension non-uniformity due to the deposition flux geometry results improved uniformity of the Josephson junction area, and therefore more uniform measured resistance across the substrate.

In some implementations, a function defining the rotational angles across the wafer surface is used to modify a lithography mask write file for a lithography tool (e.g., an electron beam lithography (EBL) system). For example, at multiple locations across a wafer surface of a wafer of a given size, a rotational angle or range of rotational angles can be defined to modify the features at the respective locations. The lithography mask write file can be modified such that certain feature dimensions and patterning elements are modified to compensate for the resulting non-uniform critical dimensions across a substrate. The modified lithography mask write file can then be used to perform lithography to define a mask. The mask may then be used for performing directional processing through the mask. For example, a deposition of multiple Josephson junctions on a substrate using this technique would exhibit improved uniformity of junction resistance.

Implementations may include one or more of the following advantages. For example, in some implementations, the techniques disclosed herein may be used to improve uniformity of performance across multiple circuit elements on a substrate. In some implementations, the presently disclosed techniques improve overall uniformity of performance of quantum computing circuit elements by compensating for fabrication variations across a substrate. For example, the presently disclosed techniques may compensate for deposition variations between a circuit element fabricated at an edge of a substrate and a circuit element fabricated near a center point of the substrate. In some implementations, improving uniformity across multiple Josephson junctions on a substrate facilitates the use of a global microwave drive method for driving/operating a set of two or more qubits using a single controller.

In some implementations, the presently disclosed techniques facilitate quantum hardware design and fabrication by using a data processing apparatus (e.g., computer) to modify a lithography mask write file by rotating features of the mask write file to align the features with a process vector of a process source for a fabrication chamber.

In some implementations, the improved uniformity allows for larger device sizes and larger wafers sizes to maintain performance, when compared to uncompensated alternatives.

The details of one or more embodiments are set forth in the accompanying drawings and the description below. Other features and advantages will be apparent from the description, the drawings, and the claims.

### BRIEF DESCRIPTION OF THE DRAWINGS

FIG. 1 is a block diagram of an exemplary environment in which an electron beam lithography write file is modified.

FIG. 2A depicts an example of an opening defining a critical dimension feature in a photoresist layer.

FIG. 2B depicts an example of an opening defining a critical dimension feature in a photoresist layer.

FIG. 3 depicts an example of a Josephson junction.

FIG. 4A is a diagram showing an example layout of multiple features defined for use in a two-step fabrication process.

FIG. 4B is a diagram showing an exemplary modified layout of multiple features defined for use in a two-step fabrication process.

FIG. 5 is a flow chart of an exemplary process for applying a rotation function to a lithography mask write file.

FIG. 6 is a flow chart of an exemplary process of fabricating a set of circuit elements with improved fabrication uniformity.

Like reference symbols in the various drawings indicate like elements.

### DETAILED DESCRIPTION

Quantum computing entails coherently processing quantum information stored in the quantum bits (qubits) of a quantum computer. Superconducting quantum computing is a promising implementation of quantum computing technology in which quantum circuit elements are formed, in part, from superconductor materials. Superconducting quantum computers are typically multilevel systems, in which only the first two levels are used as the computational basis. In certain implementations, quantum computing circuit elements, such as qubits, are operated at very low temperatures so that superconductivity can be achieved and so that thermal fluctuations do not cause transitions between energy levels. Additionally, it may be preferable that the quantum computing circuit elements are operated with low energy loss and dissipation (e.g., the quantum circuit elements exhibit a high quality factor, Q). Low energy loss and dissipation may help to avoid, e.g., quantum decoherence.

Fabrication of integrated quantum computing circuit elements with superconducting components typically involves depositing and patterning superconductor materials, dielectrics and metal layers. Certain quantum computing circuit elements, such as qubits, are constructed using Josephson junctions. A Josephson junction may be made by sandwiching a thin layer of a non-superconductive material between two layers of superconducting material. Fabrication of circuit elements can involve processes including, for example, deposition processes, material removal processes (e.g., etching), or a combination of both.

An exemplary process for fabricating a circuit element, e.g., a Josephson junction, is described as follows. A photoresist layer is deposited on a substrate and patterned to define opening regions, e.g., elongated features, within the resist through which a surface of the substrate is exposed. The opening regions within the resist may be defined by selectively exposing the resist to a source (e.g., light or an electron beam) such that the exposed portions become either soluble or insoluble when treated with a developer solution. For instance, in some implementations, an electron beam is directed onto the resist at predefined locations specified by a lithography mask write file. The lithography mask write file may define, e.g., the geometry and exposure time instructions for the electron beam to follow across the surface of the resist mask. Other exposure techniques, such as ultraviolet light exposure, may be used instead. Subsequent to exposure, the resist mask then is developed to selectively remove either the exposed or unexposed regions of the resist layer, depending on the type of resist used.

After selectively removing the resist in predefined areas, material that will form a Josephson junction may be deposited within the opened areas and on the remaining resist. For example, in some implementations, a shadow evaporation technique may be used to deposit material that will form portions of the Josephson junction. In particular, the substrate having the patterned resist is placed within a deposition chamber (e.g., a chamber of a physical vapor deposition system) at a first position and is subjected to a first superconductor deposition process. The first superconductor deposition forms a first set of deposited superconductor structures (e.g., a bottom contact for a Josephson junction) on the substrate and within the opened regions of the resist. The substrate surface facing the material being deposited may be oriented at a non-normal angle with respect to a flow direction of the deposition material, e.g., with respect to a deposition flux vector, such that a portion of the resist near the edge of opened areas blocks the deposition of at least some of the superconductor material within the opened regions.

After the first superconductor deposition step, the substrate may be transferred to air or to a separate chamber where surface oxidation of the superconductor material is promoted. In some implementations, the substrate may be left in the deposition chamber for in-situ oxidation. After oxidation, the substrate then may be subjected to a second superconductor deposition step, in which a second superconductor material is deposited to form a second set of deposition structures (e.g., a top contact for each Josephson junction). For the second superconductor deposition, the substrate may be rotated about an axis normal to the substrate surface to a second position different from the first position. In some implementations, the substrate may be rotated about the axis 90 degrees from a first position during the first deposition step to a second position during the second deposition step. Additionally, the substrate surface again may be oriented at a non-normal angle with respect to the deposition flux vector of the deposition material, such that a portion of the resist near the edge of opened areas blocks the deposition of at least some of the superconductor material within the opened regions. The angle of orientation of the substrate surface during the second deposition may be different from the angle of orientation of the substrate surface during the first deposition.

After the shadow evaporation process, the resist may be removed in a lift-off step to remove unwanted material and complete the fabrication of the Josephson junctions. Lift-off may be performed using various different solvents and/or chemistries depending on the chemical composition of the resist material.

In some cases, the fabrication process, such as the shadow evaporation process described herein, deposits, or removes material in a non-uniform manner. For example, the fabrication process may produce a film of material having a first thickness in one area of the substrate and a second, different, thickness in a second different area of the substrate.

The non-uniformity may arise for various reasons including, for example, a variation in the processing angle of the material, e.g., deposition or etching of the material, relative to the substrate surface, e.g., an angle of incidence of the process vector for the process source with respect to the features, e.g., elongated features, of the photoresist mask defining the circuit element. In some cases, the variation may arise due to substrate size (e.g., the process angle with respect to the feature directions of the features defined in the photoresist mask will be different for locations near the center of a large substrate than for locations near the edge of the substrate) and/or substrate positioning within a fabrication tool. A source-to-substrate distance between the process source and the location on the substrate can additionally result in non-uniformity. In some cases, a non-uniformity in film thickness across a substrate may arise due to shadowing and/or blocking of a process source in areas of the substrate by a mask on or near the substrate, resulting in areas of the substrate with different film thicknesses than other areas of the substrate. An angle of incidence of process source flux on the resist opening can create shadowing effects such that less material is deposited or removed in resist openings the further the resist opening is with respect to the location of a source of the deposition flux.

The non-uniformity in film thickness may adversely affect the performance of circuit elements, such as quantum computing circuit elements. For instance, in some implementations, the non-uniformity in thickness, e.g., width of a feature in-plane, normal to the surface of the wafer, or a combination thereof, of a deposited superconductor material may affect the performance (e.g., the conductance and/or the inductance) of one or more Josephson junctions at different locations across a substrate. For example, two or more identically designed Josephson junctions may be non-identical when fabricated, e.g., having different cross-sectional area of overlap between the elongated features of the Josephson junction, due to non-uniformities of deposition. The two or more non-identical Josephson junctions may then exhibit different junction performance (e.g., conductance and/or inductance).

In some instances, the electrical characteristics of the circuit element can be correlated to a non-uniformity of a fabrication process. For example, the resistance of the Josephson junction may then be correlated to a non-uniformity of deposition. Resistance, R, of a junction area of a Josephson junction is proportional to 1/A, where A is the cross-sectional area of a junction formed by an insulator layer (e.g., an oxide layer) between deposited bottom and top contacts. The cross-sectional area of the junction may include an area of the top contact that is in contact with the insulator layer between the top and bottom contacts. The resistance R for the junction may be proportional to exp(d/d₀)/A, where d is the thickness of the insulator layer between the top and bottom contacts, d₀ is a constant, and A is the area of the insulator layer in the overlap between the top and bottom contacts. As an example, for a 3″ wafer substrate, a junction resistance of a Josephson junction fabricated near the edge of the wafer may differ from a junction resistance of a Josephson junction fabricated at the center of the wafer, due to a variation in superconducting material deposition thickness at the different locations, by about 10-15%.

In some implementations, the thickness d of the insulator layer between the top and bottom contacts (e.g., the oxide layer) is uniform across a substrate, and therefore the exponential dependence on oxide thickness in determining non-uniformity of deposition (and junction resistance) may be ignored. For example, the thickness of an oxide layer may be uniform due to a uniformity in an oxidation process by which the oxide layer is promoted on top of a first deposition of a bottom contact.

The area of the junction depends on an area of overlap between the top and bottom contacts between which there is an insulating (e.g., oxide) layer. The area of overlap between the top and bottom contacts in turn may depend on the relative dimensions (e.g., length, width, height) of the contacts and the location of the contacts relative to each other. Therefore, if the dimensions and relative location of top and bottom contacts varies from Josephson junction to Josephson junction, the different junctions will exhibit different resistances.

Josephson junctions are components of many superconducting quantum computing circuit elements, including qubits. Josephson junctions in a qubit exhibiting different junction performance may directly affect the operating frequency (or phase) of the qubit. For example, the frequency of a qubit including one or more Josephson junctions is inversely proportional to a junction area of the one or more Josephson junctions, such that the frequency is proportional to the square root of the junction area.

Matching the resistances of the Josephson junctions (and therefore the frequencies or phase) may improve controllability and reproducibility of the qubits. Additionally, it may make design and/or layout of one or more qubits on a substrate easier, in part because frequency deviations between qubits may reduce a frequency range over which the one or more qubits may operate. For example, a set of three qubits may be designed to operate with a maximum qubit frequency of 6 GHz, but instead exhibit actual maximum qubit frequencies of 5.7, 5.8 and 6.1 GHz when fabricated due to non-uniformities in a Josephson junction contact deposition process. In certain implementations, such a set of qubits will be limited to operating at the lowest performing qubit (e.g., 5.7 GHz), which is less than the designed maximum qubit frequency of 6 GHz.

Other fabrication non-uniformities may affect the operation of superconducting quantum computing circuit devices and include, for example, electrode width, sidewall variation, and resist aperture variation. For example, electrode width may depend in part on the thickness of the one or more resist masks. Additionally, dimensions of one or more resist apertures for a second, subsequent deposition after a first deposition may be altered by a deposition thickness of the first deposition such that one or more electrode widths deposited in the second deposition will be affected.

The present disclosure is directed to compensating for the non-uniformities created by fabrication processes in the fabrication of circuit elements, such as quantum computing circuit elements. The compensation techniques described herein can be used to improve critical dimension uniformity of circuit elements formed by directional fabrication processes across a substrate. The compensation techniques described herein may include modifying a lithography mask write by rotating features, e.g., critical dimension feature, defined in the lithography mask write based in part on a location of the critical dimension feature in the lithography mask write file and relationship between the location and the process vector of the process source and source-to-substrate distance, and applying the modified mask write file to assist in the fabrication of the circuit element, such as a quantum computing circuit element. The modified mask write file may define one or more features that, when used to fabricate circuit structures, may compensate for the film non-uniformity created by the deposition process.

Although described in many examples in this specification with reference to compensating for directionally-dependent deposition-related non-uniformities, the techniques described herein are not limited to deposition-based processes and can be understood to be applicable to other directionally-dependent fabrication processes including, for example, material removal-based fabrication processes such as etching.

In some implementations, fabrication tools include deposition tools. Deposition tools include, for example, electron beam evaporation systems, physical vapor deposition systems, chemical vapor deposition systems, molecular beam epitaxy systems, and the like. Deposition tool parameters may vary between different deposition tools and different deposition processes, for example, source-to-substrate distances, deposition rates, range of deposition angles, and deposition beam profile.

In some implementations, fabrication tools include material removal-based tools. Material removal-based tools include, for example, reactive ion etching (RIE) tools, ion million tools, and the like.

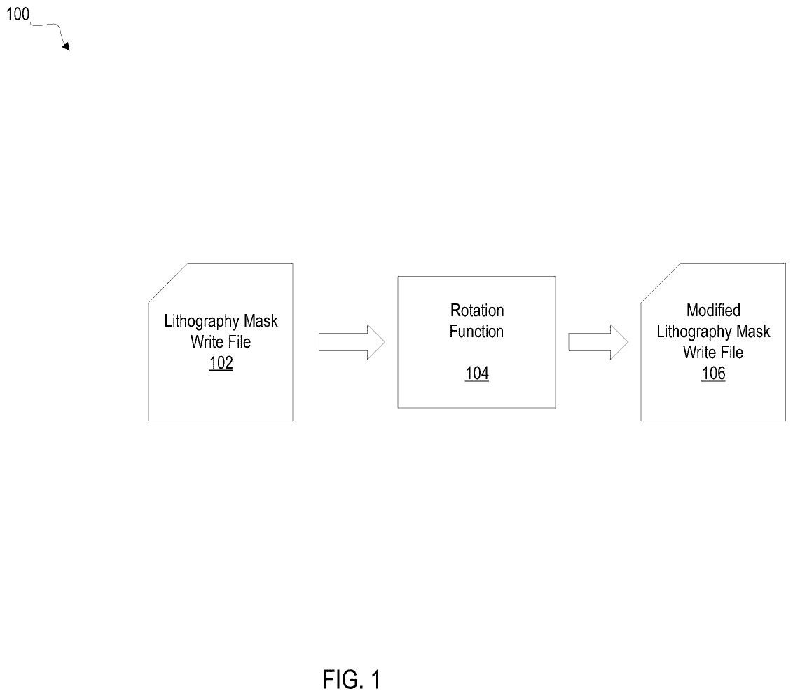

FIG. 1 is a block diagram of an exemplary process 100 for obtaining a modified mask write file. As shown in process 100, a lithography mask write file (LMWF) 102 is provided. The LMWF 102 includes a set of instructions that may be used by a lithography tool (e.g., an electron beam lithography system) to pattern a surface during an exposure process. For example, in the case of an electron beam lithography system, the instructions from LMWF 102 may include instructions for directing and scanning a focused electron beam to define a geometric feature during a resist exposure process. The instructions may also define the feature dimensions of the geometric features to be produced. Feature dimensions include, e.g., radii, curves, lengths, widths, and/or aperture openings, among other feature dimensions. For example, a feature can be an elongated feature defining a portion of a Josephson junction. In some instances, a feature dimension for the geometric feature is a critical dimension (CD) feature, where the performance of the circuit element including the CD feature is strongly correlated to the critical dimension. The instructions may also include dwell time instructions that specify the speed of the raster of an electron beam over a surface during the exposure process. In some implementations, the instructions specify how the geometric features defined by the electron beam are arranged along a two-dimensional plane.

Although described with reference to FIG. 1 as a lithography mask write file, a write file can more generally include instructions for performing a fabrication process defining geometric patterns on a substrate using a process source. For example, a write file can be used to define a directional etching process, e.g., RIE, on a substrate where the write file can define the geometric pattern on the substrate using the process source through a material removal process.

In some implementations, a LMWF 102 may include instructions for patterning of three-dimensional features. For example, the LMWF 102 may provide instructions to a lithography system such that a wall of the mask is patterned at a particular angle. In some implementations, the LMWF 102 may include instructions for using low-kV electron beam lithography to pattern three-dimension features including angled openings in a mask.

In some implementations, the fabrication of circuit elements, such as quantum computing circuit elements, may require the use of multiple LMWFs, where each LMWF provides instructions for a different mask to be used in a different fabrication step of a circuit fabrication process. For example, in some implementations, the fabrication of a Josephson junction entails the deposition and patterning of two different resist layers, in which a different mask is applied to each resist layer. The features defined by the different masks may correspond to different aspects of the Josephson junction, e.g., elongated features defining a bottom contact and a top contact.

In some implementations, the LMWF 102 includes instructions for defining features to be formed on a photomask instead of instructions for directing an electron beam during e-beam lithography. For example, the LMWF 102 may include instructions executable by computer aided design programs, such as AutoCAD®. The instructions of the LMWF may define the geometric dimensions of features to be formed on the photomask, as well as the arrangement of the features on the photomask.

For instance, in some implementations, a LMWF 102 may define the shape and locations of portions of quantum computing circuit elements. As an example, the LMWF 102 may define the shape and location of multiple different Josephson junctions across a mask. In some cases, the LMWF 102 also may specify that the shape of each quantum computing circuit element portion (e.g., each Josephson junction) is the same regardless of location within the mask. As explained herein, junction performance may vary depending on the thickness of the deposited contacts, and the thickness may be correlated with junction resistance, which, in turn, is proportional to a cross-sectional area of an oxide layer between the top and bottom contacts forming the junction. Thus, for the example in which the LMWF 102 defines multiple Josephson junctions a spatial variation in the thickness of the deposited film used to form the contacts (e.g., a variation in deposited film thickness as a function of position across the substrate surface), may result in the fabrication of multiple Josephson junctions one or more of which exhibit different junction resistances depending on the location of the junctions on the substrate.

A data processing apparatus (e.g., a computer) may formulate one or more geometric arguments to determine a geometric relationship between a process parameter for a process tool used to fabricate one or more features through the mask and the resulting effects the process parameter has on the fabricated feature across the surface of a substrate. For example, the data processing apparatus can determine a geometric relationship between deposition parameters for a deposition tool used to deposit one or more features through the LMWF defined in a photoresist layer. For example, a geometric argument specifies a geometric relationship between an angle of incidence of a process beam flux (e.g., the angle of the surface of a substrate with respect to the process beam) and a critical dimension of a feature, e.g., a thickness of deposition, at different locations across the surface of the substrate. The geometric relationships can be dependent in part on, for example, the process tool configuration, substrate size, process conditions, and the geometry of the features of the fabricated structures.

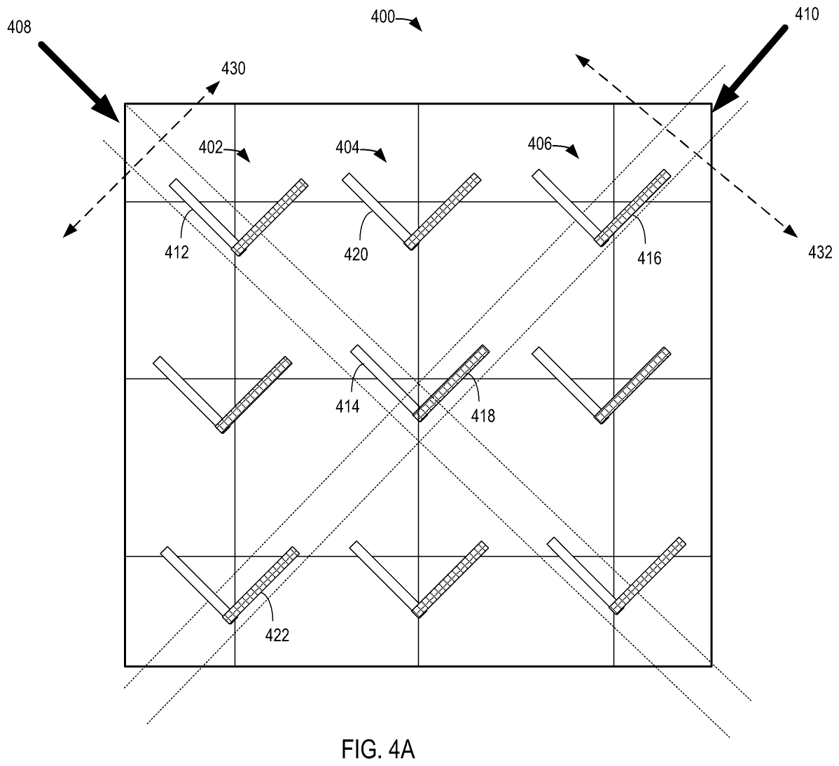

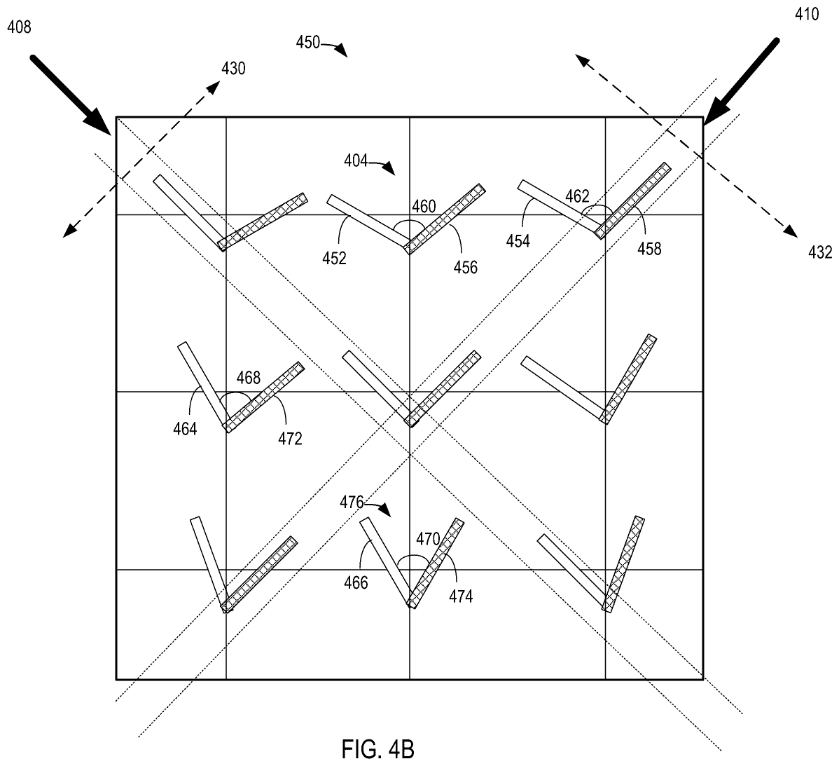

Process conditions include, e.g., process angle, a process material, and process rotation. For example, the location on the substrate of a particular Josephson junction may result in a deposition film thickness variation, due in part to the position and angle of the Josephson junction relative to the beam of depositing material, for example, as discussed with reference to FIG. 4B below. The process conditions may result in sidewall variation, resist aperture variation, film thickness variation, film width and/or length variation, or combinations thereof.

Geometry of fabricated structures can include, for example, parallel strips, crossed wires, coplanar waveguides, concentric circles, concentric squares, angled strips, tapered strips, circles, squares, and the like. In some implementations, the geometry of a set of fabricated structures affects non-uniformity of the fabricated structures. For example, a geometry including a two-step deposition process through a resist mask onto a substrate for depositing a pair of crossed wires, where each wire is deposited in a separate deposition step. A first deposition for a first wire may have the additional effect of depositing excess material on top of a resist mask. The first deposition may also result in excess material being deposited on the sidewalls of the resist mask, which may alter the intended dimensions of one or more apertures in the resist mask. A second, subsequent deposition of a second wire may thus have non-uniformities in dimension because of the altered dimensions of one or more apertures in the resist mask.

A data processing apparatus can formulate one or more geometric arguments to generate a rotation function to compensate for non-uniformities in fabrication, e.g., determining a respective rotational value at each of multiple locations of the substrate surface. In some implementations, the one or more geometric arguments may be part of a geometric model or geometric simulation. A geometric argument can relate one or more process parameters to one or more effects on deposition. For example, a geometric argument may specify the source-to-substrate distance, tilt of the substrate with respect to the source, and the size of the substrate on the fabricated structures, such that the non-uniformity is a function of the process angle (e.g., the angle of the surface of a substrate relative to the angle of a process beam).

The data processing apparatus can generate a rotation function 104 as part of a calibration process for a fabrication tool and for a given configuration of the fabrication process, e.g., for a given substrate size and a substrate tilt during processing. A calibration process can include generating respective rotation functions 104 for various configurations, e.g., for multiple combinations of substrate tilts, source-to-substrate distance (also referred to as “throw distance”), and substrate size. For example, a calibration process can generate a first rotation function 104 for a first fabrication tool having a first throw distance and a second rotation function 104 for a second fabrication tool having a second throw distance.

A rotation function 104 may be applied to the LMWF 102 to produce a modified LMWF 106 that defines a modified relative orientation of the quantum computing circuit element portions (e.g., the Josephson junction contacts) within the mask. The particular change that is applied to each quantum computing circuit element portion may be different depending on the location of the quantum computing circuit element portion within the mask, as described in further detail with reference to FIGS. 4A-4B below.

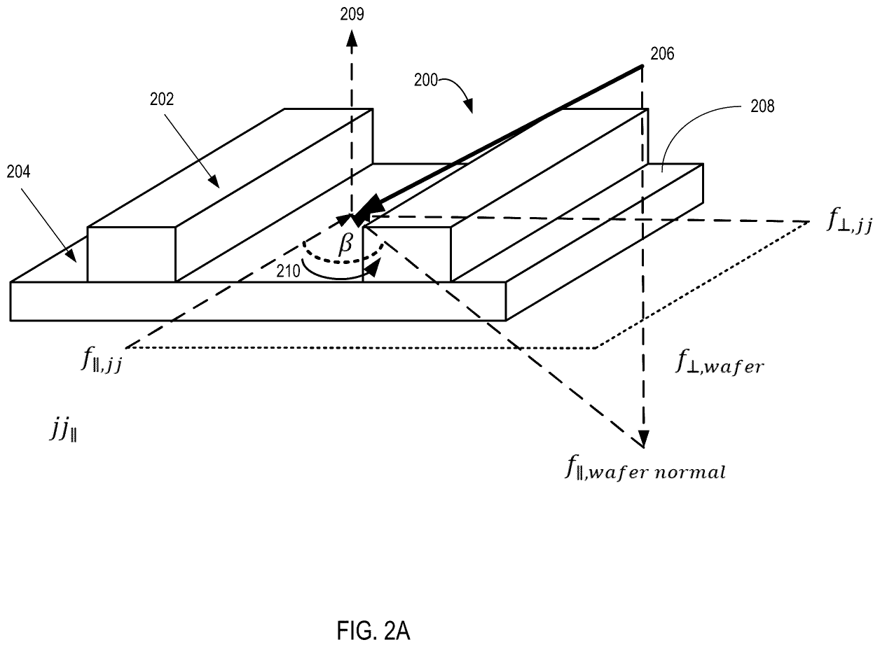

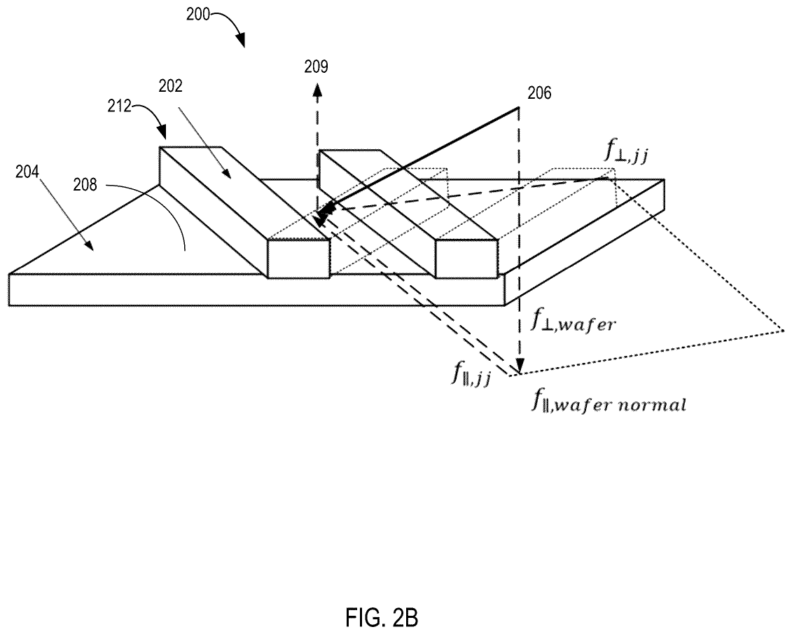

The lithography mask write file 102 can be modified to generate a modified lithography mask write file 106. Modifying the lithography mask write file 102 includes applying a rotation function 104 that modifies the lithography instructions of the LMWF 102. The modifications may include applying respective rotational values at multiple locations of the LMWF 102 corresponding to features defined by the LMWF 102. In some implementations, the modifications may include a change in dwell time instructions for an electron beam of the lithography tool. The feature changes to the LMWF 102 compensate for one or more non-uniformities in the fabrication process. That is, structures that are fabricated using the modified LMWF 106 as a mask during the fabrication process may have features, e.g., orientation of features on the substrate and with respect to each other feature of a structure, that are modified to compensate for variations resulting from the fabrication process, e.g., angle of incidence of the process beam vector and source-to-substrate distance at the location of the structure. In some examples, the features are rotated to reorient critical dimensions of the features to align with a process vector of a process source. Determining rotational values of the rotation function 104 used to modify the lithography mask write file 102 is discussed in further detail with reference to FIGS. 2A-2B below.

In some implementations, a data processing apparatus (e.g., a computer) receives a LMWF 102, and applies the rotation function to the LMWF 102 to generate a modified LMWF 106. For example, a LMWF 102 may include instructions for an electron beam lithography tool for patterning a set of features (e.g., contact pads) in a grid layout across a resist mask on a substrate. A computer program on the data processing apparatus may then receive as inputs the LMWF 102 and the rotation function 104 and apply the rotation function 104 to the LMWF 102 such that the rotation function 104 modifies one or more aspects of the features (e.g., alignment and/or orientation of the contact pads) to compensate for non-uniformities (e.g., film thickness variation) in the deposition process to be performed.

In some implementations, applying a rotational value at a location corresponding to a feature defined in the LMWF 102 includes rotating the feature such that the feature is rotated about an axis that extends normal to the substrate surface. The feature can include a critical dimension, e.g., width, length, curvature, etc., where the feature is rotated to reorient the critical dimension with respect to the process vector of the process source. For example, a feature can include a critical dimension width defined along an elongated length of the feature. The feature is rotated about an axis located within the first end of the feature, e.g., where the first end is a pivot point for the rotation and such that a second end of the feature is rotated by the rotation value. For example, a feature can be an elongated feature defining a first contact of a Josephson junction, where the elongated feature is rotated such that the first end of the elongated feature is rotated about a point within the first end of the elongated feature and the second end is rotated by the rotation value. Applying the rotation function 104 to the LMWF 102 to create a modified LMWF 106 can include, for example, rotating an orientation of a feature relative to align the feature at the location on a substrate relative to a vector defined by a deposition flux of a deposition source in a deposition chamber.

In some implementations, a rotation function 104 is a spatial mapping of multiple rotational values corresponding to multiple locations of features across an area, e.g., a substrate surface, defined in the LMWF 102. The rotation function 104 can be determined based in part on the size of a substrate on which the LMWF 102 is applied to define features in a photoresist layer of the substrate. For example, a first rotation function 104 is determined for a substrate having a first diameter, e.g., 6 inch diameter, and a second rotation function 104 is determined for a substrate having a second diameter, e.g., 12 inch diameter. In one example, for a throw distance (source-to-substrate distance) of about 700 millimeters, rotation can vary between 0 degrees in the center to about 20 degrees near the edge of an 8″ wafer. In another example, for a source-to-substrate distance of about 500 millimeters, rotation can vary between 0 degrees in the center to about 14 degrees near the edge of a 4″ wafer. A larger rotation angle can be possible at the edge of a wafer for shorter throw distances, e.g., about 30 degrees rotation at an edge of an 8″ wafer can be possible.

A rotational value of the rotation function at a location of a feature defined in the LMWF 102 can be generated using a geometric relationship defined between a process vector of a source of a fabrication system and the location of the feature on a substrate, e.g., a location defined in the photoresist layer of the substrate using the LMWF 102. Generating the rotational value can include obtaining a source-to-substrate distance for the location on the substrate of the feature, the tilt of the substrate relative to the source, and the size of the substrate, and determining an angular difference between a parallel component of the process vector, e.g., a deposition flux vector, to the surface of the substrate at the location of the feature and a vector defined along a feature direction, e.g., a critical dimension of the feature. The rotational value can be extracted using the angular difference and the source-to-substrate distance for the location of the feature on the substrate. FIGS. 2A and 2B depict examples for generating a rotational value for a feature defined in the photoresist layer of a substrate.

FIG. 2A depicts an example of an opening defining an elongated feature 200, e.g., a contact of a Josephson junction, in a photoresist layer 202 on a substrate 204. Although described with reference to FIGS. 2A and 2B using an example deposition process, the rotation of features can be applied to directional material removal processes, where the process source is a directional etching source. A deposition flux from a process source in a process chamber, e.g., deposition chamber, is incident on the substrate along a process vector, e.g., deposition flux vector 206. The deposition flux vector 206 includes a parallel component f_{∥,wafer} to the wafer surface 208 and a perpendicular component f_{⊥,wafer} to the wafer surface 208. The elongated feature 200 includes a parallel component f_{∥,jj} that is aligned with a feature direction of the elongated feature 200 and perpendicular to wafer normal 209, and a perpendicular component f_{⊥,jj} that is perpendicular to the feature direction of the elongated feature 200. A difference in angle between the parallel components of the elongated feature 200 and the deposition flux vector 206 is defined as an angle β. A rotation value for the elongated feature 200 can be defined using the angle β and a direction of rotation 210. As described above, the misalignment of the vectors f_{∥,jj} and f_{∥,wafer} can create deposition variability, e.g., non-uniform deposition of the elongated feature 200 such that the performance of a resulting device can deviate from a range of acceptable performance.

The rotation value can be applied to adjust an alignment of the vectors f_{∥,jj} and f_{∥,wafer}. As depicted in FIG. 2B, the parallel component of the elongated feature f_{∥,jj} is rotated by angle β in the direction of rotation 210 to align with the parallel component of the deposition flux vector f_{∥,wafer}. Rotating the vector vectors f_{∥,jj} of the elongated feature 200 is performed by rotating the feature defined in the LMWF 102 such that the elongated feature is defined in the photoresist layer at an updated orientation 212 with respect to the substrate. In the updated orientation 212, the length of the elongated feature is aligned with the parallel component of the deposition flux vector, which may reduce shadowing and other deposition non-uniformity.

Although depicted in FIG. 2B as a rotation where the rotation value is equal to the angle β such that the vectors f_{∥,jj} and f_{∥,wafer} are parallel after the rotation value is applied, the rotation value can be less than the angle β. In some examples, the rotation value is a different magnitude than the angle β such that the degree of rotation applied to the feature by the rotation function 104 is less than or greater than the angle β. A rotation value can be limited to a threshold magnitude or a range of magnitudes, beyond which may impact other factors related to the fabrication of the quantum computing circuit element including the feature. For example, a rotation value can be selected to be less than the angle β to maintain a threshold overlap between the electrical contact defined by the feature and another electrical contact to form a Josephson junction. Further discussion of a threshold overlap is discussed with reference to FIG. 4B below.

In some implementations, a quantum computing circuit element can be defined using two or more LMWF 102. In some examples, a respective LMWF 102 can be used to define respective features of a circuit element, e.g., each of a first and a second contact of a Josephson junction is defined on a respective LMWF 102. In such cases, each of the LMWF 102 can be modified by a respective rotation function depending on the process parameters, e.g., angle of incidence of the process vector, of the process source for a fabrication process corresponding to the masked features defined in the LMWF. For example, a first process step may have a unique non-uniform process variation relative to other process steps within the fabrication process. Differences in non-uniformity of fabrication processes between process steps may be due to a variety of factors including, a difference in substrate rotation in the different steps, a difference in the angle of orientation of the substrate surface relative to a process source, a difference in source-to-substrate distance of the location with respect to each source, and a difference in shadow effects from other layers or features on the substrate, e.g., by the resist mask between deposition steps. A shadow effect may occur when a part of a substrate area is shadowed or obscured by another layer, e.g., by a resist mask, such that a process beam is limited or blocked from line of sight of the process region on the substrate area. Another shadow effect may occur when a surface of a substrate is angled with respect to the process beam such that the process beam is shadowed or obscured from the process region on the substrate area.

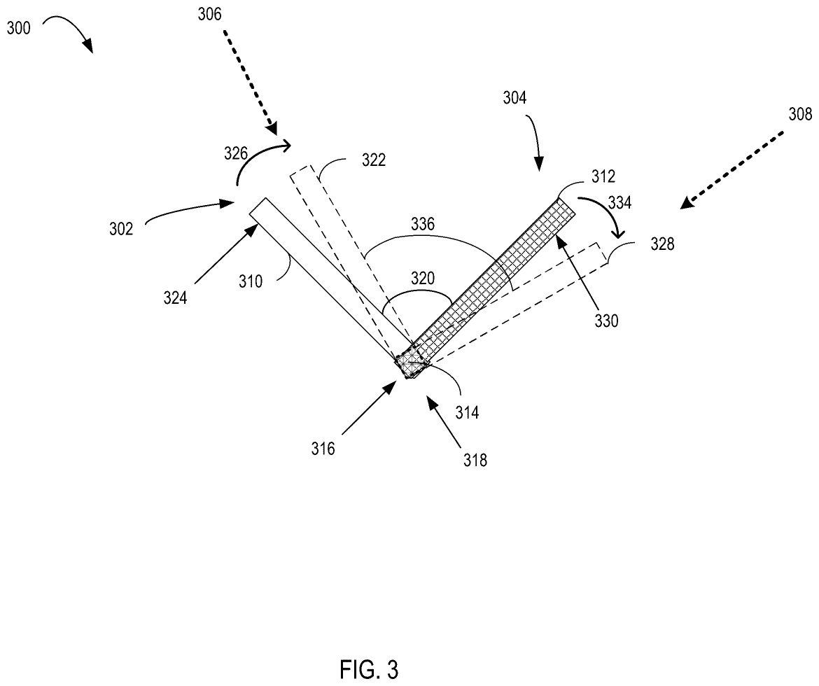

In some implementations, the circuit elements include multiple critical dimensions. FIG. 3 depicts an example of a Josephson junction 300. Josephson junction 300 includes two elongated features, first elongated feature 302 and a second elongated feature 304 of the mask for defining respective openings in a photoresist layer and through which respective a first deposition from a first direction 306 and a second deposition flux 308 from a second direction are performed in a deposition tool. Each of elongated features 302 and 304 are defined in the LMWF in respective first orientations 310 and 312. The two elongated features 302, 304 are oriented with respect to each other with an overlap region 314 composed of the respective second ends 316, 318 of each of the elongated features.

The two elongated features 302, 304 form an initial angle 320 with respect to each other, e.g., a 90-degree angle. In some implementations, the angle formed between the elongated features can be larger, e.g., oblique, or smaller, e.g., acute.

A first orientation 310 of a first elongated feature 302 can be reoriented to a second orientation 322, where the first end 324 of the feature 302 is rotated in-plane by an angle 326, e.g., a rotation value, towards the vector of the corresponding first deposition flux 306, and where a second end 316 of the feature 302 is rotated about a point centered within the second end 316 of the elongated feature 302. In such cases, the second end 316 of the elongated feature is a pivot point of the rotation, e.g., to maintain threshold overlap region 314 with the second elongated feature 304.

A first orientation 312 of a second elongated feature 304 can be reoriented to a second orientation 328, where the first end 330 of the feature 304 is rotated towards the vector of the corresponding second deposition flux 308, and where a second end 318 of the elongated feature is rotated about a point centered within the second end 318 of the elongated feature by an angle 334, e.g., a rotation value.

In some implementations, the directions of rotation, e.g., clockwise or counterclockwise, may be the same or different. Although depicted in FIG. 3 as rotating both of the elongated features, one or none of the elongated features defined in the LMWF can be reorientated to generate a modified LMWF.

As a result of the rotation of one or both of the elongated features 302, 304, an updated angle 336 is formed between the two elongated features which can be different from an original angle 320. For example, an original angle 320 can be nominally 90 degrees and an updated post-rotation angle can be an oblique angle, e.g., as depicted in FIG. 3, or an acute angle.

In some implementations, the data processing apparatus can validate the modified LMWF using one or more modification rules to ensure that the updated features defined in the modified LMWF meet a set of device parameters. In some examples, a modification rule includes a threshold overlap in the overlap region 314 of the respective second ends 316, 318 of the elongated features 302 and 304 can be enforced when applying the rotation to one or both of the elongated features. A maximum rotation value for respective elongated features can be enforced to prevent over-rotation, e.g., for features located at the edge of the substrate, such that a threshold overlap condition between the elongated features is met after the rotation of one or both of the elongated features. In some examples, a modification rule that includes a range of rotation values can be enforced such that a threshold overlap condition between the elongated features is met after the rotation of one or both of the elongated features. In some examples, a modification rule includes a misalignment tolerance between the first ends of the elongated features and other quantum computing circuit elements in proximity to or in contact with the first ends of the elongated features.

In some implementations, the one or more modification rules depends in part on the geometry of the quantum computing circuit elements defined in the LMWF 102. For example, a quantum computing circuit element can be one or more critical dimensions, e.g., widths, lengths, curvature, etc., defined in the feature which may have an increased sensitivity to alignment and can require a more precise alignment of the features.

In some implementations, the one or more modification rules depends in part on a number of input parameters including, for example, critical dimension(s) of features, tilt angle of the substrate during processing, and thickness of the layers, e.g., photoresist layer(s). For example, modification rules can enforce a range of angles defined between two critical dimension features, e.g., forming a Josephson junction, to be ±60°, e.g., where the two critical dimension features can be separated by an angle between 30° and 150°, e.g., for a given size of Josephson junction and photoresist thickness.

In some implementations, the data processing apparatus performs an optimization process to refine the rotational values applied to the features defined in the LMWF to generate the modified LMWF. The optimization process can include an iteration between applying a current set of rotational values to the features, e.g., critical dimension features, validating the modified orientations of the features against the one or more modification rules, and updating the set of rotational values to generate an updated set of rotational values to correct for any violation of the one or more modification rules. For example, an updated set of rotational values can limit a magnitude of a rotational value to prevent a first feature from misaligning with respect to a corresponding second feature, e.g., to prevent misaligning the contacts forming a Josephson junction.

In some implementations, the one or more modification rules are enforced automatically or semi-automatically using design rule checking (DRC). For example, the DRC can be performed using an automated or semi-automated model to validate each of the modified orientations of the elongated features of the modified LMWF. A human operator may be able to view the results of the validation process including violations of the DRC and update the violating features to conform to the modification rules. Some or all of the process of the DRC can be implemented using a trained machine learning model.

In some implementations, the LMWF 102 defines a lithography pattern that is copied multiple times across a mask using a stitching process. For example, a LMWF 102 can define multiple copies of a quantum computing circuit element, e.g., multiple copies of a contact of a Josephson junction.

A rotation function 104 may be generated and applied to different regions of the mask defined by the LMWF 102 including different rotation values for different regions each including one or more features about the LMWF 102. The rotation value(s) that will be used at each different region may depend on the expected process variation to occur in that region. For example, a rotation value applied to a feature pattern in a region adjacent to a mask edge may differ from a rotation value applied to the same feature pattern that is located in a region adjacent to a central portion of the mask.

FIG. 4A is a diagram showing an example layout of multiple features defined for use in a two-step deposition process. Though depicted in FIGS. 4A and 4B using the example of Josephson junctions, the modifications to the layouts of multiple features defined in write files for fabricating circuit elements can be applied to other types of features and fabrication processes that require more or fewer steps than a two-step fabrication process and including deposition, material removal, or a combination of both. The layout can be defined in two or more photoresist layers using two or more LMWF 102, e.g., a respective mask write file to define each elongated feature forming a contact of the Josephson junction. The masked features can be transferred to a respective photoresist layer using an exposure tool operated according to instructions defined in each of the lithography mask write files 102. The LMWF 102 contains instructions for the lithography tool (e.g., electron beam lithography tool) regarding the dimensions and layout with respect to a substrate of each feature such that the electron beam may selectively cure the areas where the features occur or the areas where the features do not occur, depending on the type of resist used. The instructions of the LMWF also include a dwell time or speed at which the electron beam rasters the surface, curing through the thickness of the resist layer.

As depicted in FIG. 4A, the layout 400 includes multiple Josephson junctions, e.g., junctions 402, 404, 406, formed using two elongated features using a two-deposition process from two deposition fluxes, e.g., deposition fluxes 408 and 410. The deposition fluxes 408 and 410 are incident at two directions with respect to the wafer surface such that a first deposition flux 408 is nominally aligned with respective lengths along the first set of elongated features of the respective Josephson junctions, e.g., features 412, 414, and a second deposition flux 410 is nominally aligned with respective lengths along the second set of elongated features of the respective Josephson junctions, e.g., features 416, 418.

In some implementations, it may be determined, as described above with reference to FIGS. 2A and 2B, that the deposition parameters result in a non-uniform deposition. For example, feature 420 is offset laterally from the deposition flux 408. In another example, feature 422 is located longitudinally at a longer source-to-substrate distance from the source of the deposition flux 410 than feature 416. In both instances, the variation in location of the features 420 and 422 can result in non-uniform deposition.

In some implementations, the one or more LMWF can be modified such that the layout of the one or more of the elongated features of a mask is rotated with respect to the direction of the deposition flux corresponding to the deposition through the masked feature. A rotation value, e.g., a degree of rotation and a direction of rotation, for an elongated feature depends in part on a location of the feature with respect to the deposition source. The location of the feature on the mask with respect to the deposition source can impact a source-to-substrate distance between the deposition source and the location of the feature as well as the offset between the vector along the length of the feature and the parallel component of the deposition flux vector. In some examples, a feature located further away laterally (e.g., along axis 430 perpendicular to the deposition flux vector 408) from the deposition flux vector is rotated by a larger degree of rotation than a feature that is located in-line with the path of the deposition flux vector. In some examples, a feature located further away longitudinally (e.g., along axis 432 perpendicular to the deposition flux vector 410) from the deposition vector is rotated by a larger degree of rotation than a feature that is located closer to deposition source, e.g., a feature located at a larger source-to-substrate distance is rotated by a larger degree of rotation than a feature located at a shorter source-to-substrate distance.

FIG. 4B is a diagram showing exemplary modified layout 450, e.g., a modification of the layout depicted in FIG. 4A, using a rotation function, such as the rotation functions described herein. As described with reference to FIG. 2B, the rotation of the feature can reorient the length of one or more of the features of the corresponding LMWF to align with a parallel component of the deposition flux vector.

In order to reduce variability across the wafer, at least a portion of the features defined in the photoresist are rotated to align the feature with respect to the deposition flux vector such that features at different locations about the wafer surface are oriented with respect to the deposition flux vector in a more uniform manner across the wafer. Rotating the elongated feature includes adjusting a position of the second end of the elongated feature to dispose, e.g., orient, the vector along the feature direction of the elongated feature with the parallel component of the deposition flux vector to the surface and corresponding to the location of the elongated feature on the substrate, as discussed with reference to FIGS. 2A, 2B above. For example, as depicted in FIG. 4B, the layout 450 includes features of layout 400 which are rotated by respective rotation values to align one or both of the elongated features of the Josephson junction towards the respective deposition flux vector.

In some implementations, disposing the vector along the feature direction of the elongated feature with the parallel component of the process vector includes rotating the second end of the elongated feature to decrease an angle difference between the vector along the feature direction and the parallel component of the process vector is decreased from an initial angle difference. Decreasing the angular difference can be reducing the difference by a rotation value that is less than a value of the initial angle difference. Decreasing the angular difference can be reducing by a threshold rotation value for the location of the elongated feature on the surface of the substrate. For example, a rotation value for a feature that is located at an edge of the substrate can be limited to a threshold rotation value, e.g., to prevent the elongated feature from being over-rotated and to maintain a threshold overlap region between the elongated feature and a corresponding second elongated feature of the Josephson junction.

In the example depicted in FIG. 4B, a first set of elongated features forming a first portion of the respective Josephson junctions are rotated to align along a first direction of a deposition flux vector 408. For example, first elongated features 452, 454 are rotated towards deposition flux vector 408 in a counterclockwise direction to form angles 460, 462 with respect to corresponding second elongated features 456, 458. In another example, first elongated features 464, 466 are rotated towards deposition flux vector 408 in a clockwise direction to form angles 468, 470 with respect to corresponding second elongated features 472, 474. In either of the previous examples, rotation of the first set of elongated features is towards the first deposition flux vector 408, where a rotation value depends in part on a magnitude of the lateral offset of the feature from the deposition flux vector 408 along axis 430 and a source-to-substrate distance between the source of the deposition flux vector 408 and the location of the feature. For example, angles of rotation of the elongated features become larger as the location of the feature is located further laterally away from the deposition flux vector 408 along the axis 430 perpendicular to vector 408.

In the example depicted in FIG. 4B, a second set of elongated features forming a second portion of the respective Josephson junction on the mask are rotated to align along a second direction of a deposition flux vector 410. For example, second elongated features 456, 472 are rotated towards deposition flux vector 410 in a clockwise direction to form angles 460, 468 with respect to corresponding first elongated features 452, 464. In another example, second elongated feature 474 is rotated towards deposition flux vector 410 in a clockwise direction to form an angle 470 with respect to corresponding first elongated feature 466. In either of the previous examples, rotation of the second set of elongated features is towards the second deposition flux vector 410, where a rotation value depends in part on a magnitude of the lateral offset of the feature from the deposition flux vector 410 along axis 432 and a source-to-substrate distance between the source of the deposition flux vector 410 and the location of the feature. For example, angles of rotation of the elongated features become larger as the location of the feature is located further laterally away from the deposition flux vector 410 along the axis 432 perpendicular to vector 410.

In any of the previous examples of FIG. 4B, rotation of the first and second sets of elongated features is towards the respective deposition flux vectors 408, 410, where a rotation value depends in part on a magnitude of the lateral offset of the feature from the deposition flux vector along a perpendicular axis to the deposition flux vector and a source-to-substrate distance between the source of the respective deposition flux vector and the location of the feature. For example, angles of rotation of the elongated features become larger as the location of the feature is located further laterally away from the deposition flux vector.

The resulting angles between the first and second elongated features become increasingly acute as the location of the Josephson junction is located further laterally away from the sources of the deposition flux vectors 408, 410 along the axis of the deposition flux vectors. More generally, as result of the different degrees of rotation of the elongated features, the further the location of the feature longitudinally from the source and laterally from the deposition flux vector, the more extreme the rotation of the feature. For example, a Josephson junction 476 located further away from the locations of the source(s) during the first and second depositions will have respective elongated features 466, 474 rotated to form an acute angle 470 in the modified mask. In another example, a Josephson junction 404 located closer to the locations of the source(s) during the first and second depositions will have respective elongated features 452, 456 rotated to form an oblique angle 460 in the modified mask layout 450.

The modified LMWFs 106, e.g., masks used to define layout 450, may be used to perform lithography, where each modified LMWF 106 provides instructions (e.g., location and dwell times) to a lithography tool to define a set of the features in corresponding photoresist layers on the substrate.

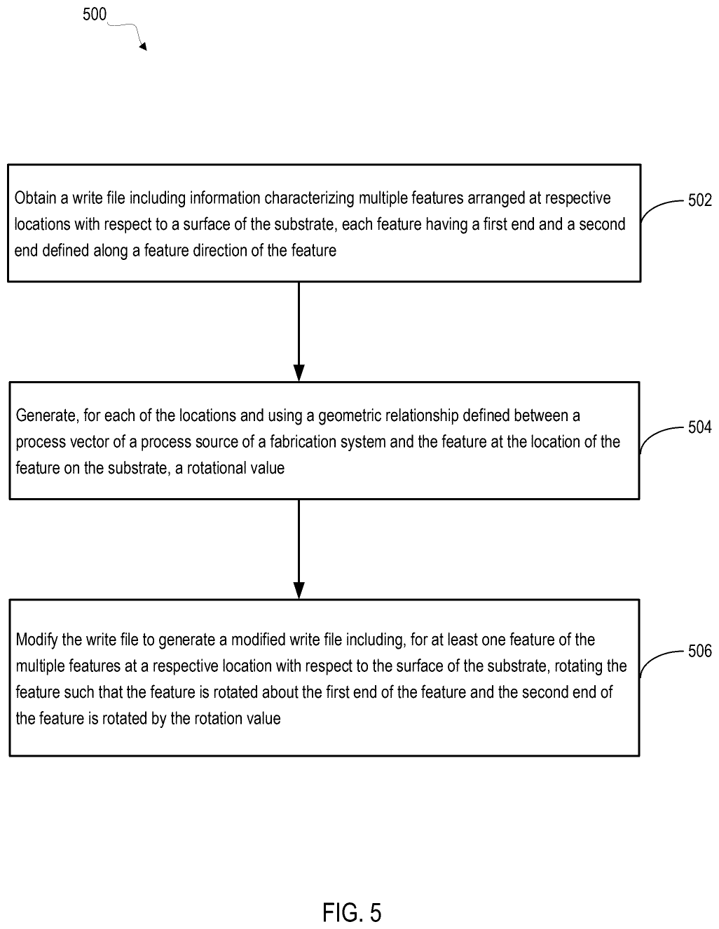

FIG. 5 is a flow chart of an example process 500 for applying a rotation function to a lithography mask write file. For convenience, the process 500 will be described as being performed by a data processing system of one or more computers, located in one or more locations, and programmed appropriately in accordance with this specification.

A data processing system obtains (502) a write file, e.g., a lithography mask write file (LMWF) 102, including a set of instructions defining a pattern having at least one feature. The write file characterizes multiple features, e.g., elongated features having a critical dimension, arranged at respective locations with respect to a surface of the substrate, each feature having a first end and a second, opposing end the first end and defined along a feature direction of the feature. For example, the instructions in a LMWF 102 may be used to perform lithography on a photoresist mask for use in fabricating a set of Josephson junctions on a sample (e.g., a substrate). The fabrication process can involve at least one fabrication process, the fabrication process having a set of process parameters. In some examples, the fabrication process includes two depositions using a shadow evaporation process, the fabrication process having a set of deposition parameters. Each of the process parameters may have a non-uniformity effect on fabrication of the set of circuit elements on the substrate.

The data processing system generates (504), for each of the locations and using a geometric relationship defined between a process vector of a process source of a fabrication system and the feature at the location of the feature on the substrate, a rotational value. Each rotational value corresponding to a feature compensates for the non-uniformity deposition effects resulting from the process parameters used in the fabrication process by modifying the orientation of the feature, e.g., modifying the orientation of a critical dimension of the feature, as defined in a LMWF 102 to generate a modified LMWF 106. For example, a short source-to-substrate distance in a deposition tool (e.g., an electron beam evaporation system) may cause a radially-dependent non-uniformity where thickness of deposition varies radially outward from the center of the substrate. Additionally, an offset in uniformity from the center of the substrate may result from process beam location, substrate tilt, substrate offset from center, angle of incidence of the process beam on the substrate, or the like.

The data processing system modifies (506) the write file to generate a modified write file including, for at least one feature of the multiple features at a respective location with respect to the surface of the substrate, rotating the feature such that the feature is rotated about the first end of the feature and the second end of the feature is rotated by the rotation value. The modified write file, e.g., LMWF 106, may have some or none of the same instructions from the original write file, e.g., LMWF 102. For example, lithography is performed using the modified LMWF 106 to define a pattern that will be used for shadow evaporation of a superconducting material to form a set of Josephson junctions on the sample substrate.

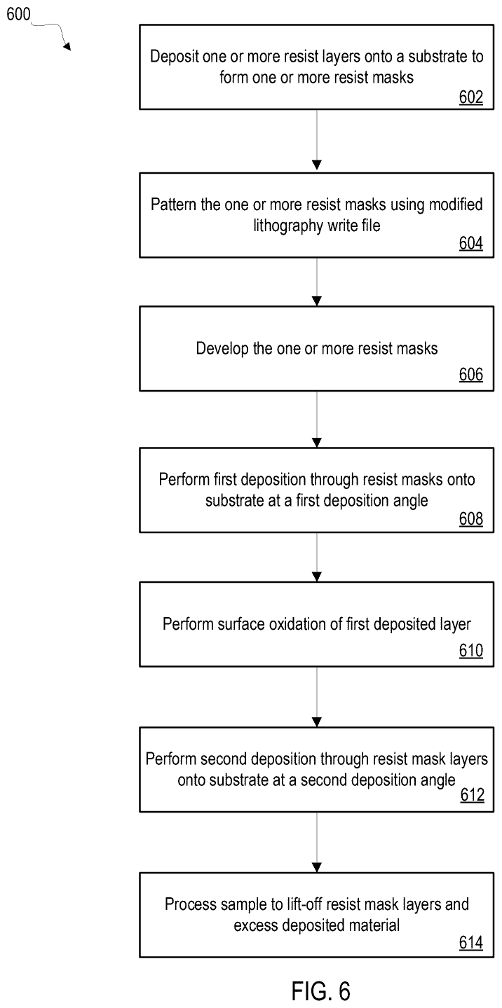

FIG. 6 is a flow chart of an example process for fabricating a set of Josephson junctions with improved junction resistance uniformity on a sample substrate. One or more resist layers are deposited onto a substrate to form one or more resist masks (602). Deposition of resist layers may be through spin coating. Various compositions of resist may be used including poly(methyl methacrylate) (PMMA). Resists may be positive or negative resists, where the positive resist is exposed in regions that will be removed from the resist mask and negative resist is exposed in all the regions that will be part of the resist mask.

The one or more resist masks are patterned using a modified LMWF (604) as described with reference to FIG. 5. Each mask may be patterned using a different modified LMWF. Each resist mask is developed such that the features defined by the modified LMWF are revealed (606). For example, a square defined by a modified LMWF in a positive resist mask will be developed (e.g., using a developer solution) to wash away the resist that is within the defined feature, exposing a substrate layer underneath. Once the resist mask is defined, the shadow evaporation process proceeds.

One or more depositions are performed in a deposition tool (e.g., electron beam evaporation system, physical vapor deposition system, molecular beam epitaxy). A first deposition is performed (608) through the one or more resist masks. The first deposition of a layer of superconducting material may be performed at a first deposition angle on a substrate positioned at a first position in the deposition chamber. For example, a substrate surface deposition angle of 45° degrees (relative to the deposition beam axis) may be selected for the first deposition of a bottom contact of the Josephson junctions.

Following the first deposition, a surface oxidation is performed on the first deposited layer (610). The surface oxidation process may be performed in air or in a controlled environment. The controlled environment may be a separate chamber from the chamber where deposition is occurring. In some implementations, high-purity oxygen is used to promote oxidation of the first deposited layer of superconducting material.

After oxidizing the surface of the first deposited layer, the sample substrate is returned to the deposition tool, and a second deposition through the resist mask layers onto the substrate is performed (612). The second deposition is performed at a second substrate surface deposition angle (relative to the deposition beam axis). In some implementations, the second deposition angle may be orthogonal to the first deposition angle. In some implementations, the substrate is rotated to a second position in the deposition chamber different from the first position.

When the deposition steps are completed, the sample is processed to lift-off the resist mask layers as well as any excess deposition (614). For example, one or more solvents (e.g., acetone), other chemical compounds (resist strippers), ultrasonic immersion, heated bath, or a combination thereof may be used.

In some implementations, some or all of the processes and characterization techniques mentioned above take place in a controlled environment which may include a high-purity vacuum chamber, temperatures below the superconducting temperature of the superconducting material, or a combination thereof.

An example of a superconductor material that can be used in the formation of quantum circuit elements is aluminum. Another example of a superconductor material that can be used in the formation of quantum circuit elements is niobium. Aluminum and/or niobium may be used in combination with a dielectric to establish Josephson junctions, which are a common component of quantum circuit elements. Examples of quantum circuit elements that may be formed with superconductor materials include circuit elements such as superconducting co-planar waveguides, quantum LC oscillators, qubits (e.g., flux qubits or charge qubits), superconducting quantum interference devices (SQUIDs) (e.g., RF-SQUID or DC-SQUID), inductors, capacitors, transmission lines, ground planes, among others.

Aluminum may also be used in the formation of superconducting classical circuit elements that are interoperable with superconducting quantum circuit elements as well as other classical circuit elements based on complementary metal oxide semiconductor (CMOS) circuitry. Examples of classical circuit elements that may be formed with aluminum include rapid single flux quantum (RSFQ) devices, reciprocal quantum logic (RQL) devices and ERSFQ devices, which are an energy-efficient version of RSFQ that does not use bias resistors. Other classical circuit elements may be formed with aluminum as well. The classical circuit elements may be configured to collectively carry out instructions of a computer program by performing basic arithmetical, logical, and/or input/output operations on data, in which the data is represented in analog or digital form.

Processes described herein may entail the deposition of one or more materials, such as superconductors, dielectrics and/or metals. Depending on the selected material, these materials may be deposited using deposition processes such as chemical vapor deposition, physical vapor deposition (e.g., evaporation or sputtering), or epitaxial techniques, among other deposition processes. Processes described herein may also entail the removal of one or more materials from a device during fabrication. Depending on the material to be removed, the removal process may include, e.g., wet etching techniques, dry etching techniques, or lift-off processes.

Implementations of the quantum subject matter and quantum operations described in this specification may be implemented in suitable quantum circuitry or, more generally, quantum computational systems, including the structures disclosed in this specification and their structural equivalents, or in combinations of one or more of them. The term “quantum computational systems” may include, but is not limited to, quantum computers, quantum information processing systems, quantum cryptography systems, or quantum simulators.

The terms quantum information and quantum data refer to information or data that is carried by, held or stored in quantum systems, where the smallest non-trivial system is a qubit, e.g., a system that defines the unit of quantum information. It is understood that the term “qubit” encompasses all quantum systems that may be suitably approximated as a two-level system in the corresponding context. Such quantum systems may include multi-level systems, e.g., with two or more levels. By way of example, such systems can include atoms, electrons, photons, ions or superconducting qubits. In many implementations the computational basis states are identified with the ground and first excited states, however it is understood that other setups where the computational states are identified with higher level excited states are possible. It is understood that quantum memories are devices that can store quantum data for a long time with high fidelity and efficiency, e.g., light-matter interfaces where light is used for transmission and matter for storing and preserving the quantum features of quantum data such as superposition or quantum coherence.

Quantum circuit elements may be used to perform quantum processing operations. That is, the quantum circuit elements may be configured to make use of quantum-mechanical phenomena, such as superposition and entanglement, to perform operations on data in a non-deterministic manner. Certain quantum circuit elements, such as qubits, may be configured to represent and operate on information in more than one state simultaneously. Examples of superconducting quantum circuit elements that may be formed with the processes disclosed herein include circuit elements such as co-planar waveguides, quantum LC oscillators, qubits (e.g., flux qubits or charge qubits), superconducting quantum interference devices (SQUIDs) (e.g., RF-SQUID or DC-SQUID), among others.

In contrast, classical circuit elements generally process data in a deterministic manner. Classical circuit elements may be configured to collectively carry out instructions of a computer program by performing basic arithmetical, logical, and/or input/output operations on data, in which the data is represented in analog or digital form. In some implementations, classical circuit elements may be used to transmit data to and/or receive data from the quantum circuit elements through electrical or electromagnetic connections. Examples of classical circuit elements that may be formed with the processes disclosed herein include rapid single flux quantum (RSFQ) devices, reciprocal quantum logic (RQL) devices and ERSFQ devices, which are an energy-efficient version of RSFQ that does not use bias resistors. Other classical circuit elements may be formed with the processes disclosed herein as well.

During operation of a quantum computational system that uses superconducting quantum circuit elements and/or superconducting classical circuit elements, such as the circuit elements described herein, the superconducting circuit elements are cooled down within a cryostat to temperatures that allow a superconductor material to exhibit superconducting properties.

While this specification contains many specific implementation details, these should not be construed as limitations on the scope of what may be claimed, but rather as descriptions of features that may be specific to particular implementations. Certain features that are described in this specification in the context of separate implementations can also be implemented in combination in a single implementation. Conversely, various features that are described in the context of a single implementation can also be implemented in multiple implementations separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

One or more processes described herein, such as one or more of the steps of processes described in this specification, may be performed by a data processing apparatus. The term “data processing apparatus” encompasses all kinds of apparatus, devices, and machines for processing data, including by way of example a programmable processor, a computer, a system on a chip, or multiple ones, or combinations, of the foregoing. The apparatus can include special purpose logic circuitry, e.g., an FPGA (field programmable gate array) or an ASIC (application-specific integrated circuit). The apparatus can also include, in addition to hardware, code that creates an execution environment for the computer program in question, e.g., code that constitutes processor firmware, a protocol stack, a database management system, an operating system, a cross-platform runtime environment, a virtual machine, or a combination of one or more of them. The apparatus and execution environment can realize various different computing model infrastructures, such as web services, distributed computing and grid computing infrastructures.

A computer program (also known as a program, software, software application, script, or code) can be written in any form of programming language, including compiled or interpreted languages, declarative or procedural languages, and it can be deployed in any form, including as a stand-alone program or as a module, component, subroutine, object, or other unit suitable for use in a computing environment. A computer program may, but need not, correspond to a file in a file system. A program can be stored in a portion of a file that holds other programs or data (e.g., one or more scripts stored in a markup language document), in a single file dedicated to the program in question, or in multiple coordinated files (e.g., files that store one or more modules, sub-programs, or portions of code). A computer program can be deployed to be executed on one computer or on multiple computers that are located at one site or distributed across multiple sites and interconnected by a communication network.

The processes and logic flows described in this specification can be performed by one or more programmable processors executing one or more computer programs to perform actions by operating on input data and generating output. The processes and logic flows can also be performed by, and apparatus can also be implemented as, special purpose logic circuitry, e.g., a FPGA (field programmable gate array) or an ASIC (application-specific integrated circuit).

Processors suitable for the execution of a computer program include, by way of example, both general and special purpose microprocessors, and any one or more processors of any kind of digital computer. Generally, a processor will receive instructions and data from a read-only memory or a random-access memory or both. The essential elements of a computer are a processor for performing actions in accordance with instructions and one or more memory devices for storing instructions and data. Generally, a computer will also include, or be operatively coupled to receive data from or transfer data to, or both, one or more mass storage devices for storing data, e.g., magnetic, magneto-optical disks, or optical disks. However, a computer need not have such devices. Moreover, a computer can be embedded in another device, e.g., a mobile telephone, a personal digital assistant (PDA), a mobile audio or video player, a game console, a Global Positioning System (GPS) receiver, or a portable storage device (e.g., a universal serial bus (USB) flash drive), to name just a few. Devices suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto-optical disks; and CD-ROM and DVD-ROM disks. The processor and the memory can be supplemented by, or incorporated in, special purpose logic circuitry.

To provide for interaction with a user, embodiments of the subject matter described in this specification can be implemented on a computer having a display device, e.g., a CRT (cathode ray tube) or LCD (liquid crystal display) monitor, for displaying information to the user and a keyboard and a pointing device, e.g., a mouse or a trackball, by which the user can provide input to the computer. Other kinds of devices can be used to provide for interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's user device in response to requests received from the web browser.

Embodiments of the subject matter described in this specification can be implemented in a computing system that includes a back-end component, e.g., as a data server, or that includes a middleware component, e.g., an application server, or that includes a front-end component, e.g., a user computer having a graphical user interface or a Web browser through which a user can interact with an implementation of the subject matter described in this specification, or any combination of one or more such back-end, middleware, or front-end components. The components of the system can be interconnected by any form or medium of digital data communication, e.g., a communication network. Examples of communication networks include a local area network (“LAN”) and a wide area network (“WAN”), an inter-network (e.g., the Internet), and peer-to-peer networks (e.g., ad hoc peer-to-peer networks).

The computing system can include users and servers. A user and server are generally remote from each other and typically interact through a communication network. The relationship of user and server arises by virtue of computer programs running on the respective computers and having a user-server relationship to each other. In some embodiments, a server transmits data (e.g., an HTML page) to a user device (e.g., for purposes of displaying data to and receiving user input from a user interacting with the user device). Data generated at the user device (e.g., a result of the user interaction) can be received from the user device at the server.

While this specification contains many specific implementation details, these should not be construed as limitations on the scope of any features or of what may be claimed, but rather as descriptions of features specific to particular embodiments. Certain features that are described in this specification in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. For example, the actions recited in the claims can be performed in a different order and still achieve desirable results. In certain circumstances, multitasking and parallel processing may be advantageous. Moreover, the separation of various components in the implementations described above should not be understood as requiring such separation in all implementations.

A number of implementations have been described. Nevertheless, it will be understood that various modifications may be made without departing from the spirit and scope of the invention. Other implementations are within the scope of the following claims.

1. A computer-implemented method of fabricating a circuit element on a substrate by a fabrication system comprising:
obtaining, by one or more processors, a write file comprising information characterizing a plurality of features arranged at a plurality of locations with respect to a surface of the substrate, each feature having a first end and a second end defined along a first feature direction of the feature;
generating, by the one or more processors and for each of the plurality of locations and using a geometric relationship defined between a process vector of a process source of the fabrication system and the location of the feature on the substrate, a rotational value; and
modifying, by the one or more processors, the write file to generate a modified write file comprising
for at least one feature of the plurality of features at a respective location with respect to the surface of the substrate, rotating the first feature direction of the feature about an axis normal to the surface of the substrate by the rotation value.

2. The method of claim 1, wherein the write file is a lithography mask write file, and wherein the geometric relationship is defined between a deposition flux vector of a deposition source of the fabrication system and the location of the feature on the substrate.

3. The method of claim 1, wherein rotating the first feature direction of the feature about the axis comprises rotating the feature about the axis located within the second end such that the first end of the feature is rotated by the rotation value.

4. The method of claim 1, wherein generating the rotational value comprises:
obtaining a source-to-substrate distance for a substrate location of the feature on the substrate;
determining an angular difference between a component of the process vector and a feature vector along the first feature direction of the feature, the component of the process vector being parallel to the surface of the substrate at the location of the feature on the substrate; and
generating, using the angular difference and the source-to-substrate distance for the substrate location of the feature on the substrate, the rotational value.

5. The method of claim 4, wherein rotating the feature comprises adjusting a position of the second end of the feature to dispose the feature vector to be aligned with the component of the process vector.

6. The method of claim 4, wherein generating the rotational value further comprises
determining, using the source-to-substrate distance, a maximum rotational value for the feature,
wherein a first location of the feature corresponds to a first maximum rotational value and a second, different location of a different feature corresponds to a second, different maximum rotational value.

7. The method of claim 2, wherein the information of the write file characterizes a first feature and a second feature collectively defining contact portions of a Josephson junction, the information of the write file further characterizing an overlap region including a respective portion of each of a first end of the first feature and a first end of the second feature, the method further comprising:
generating, for the first feature and using a geometric relationship defined between a first deposition flux vector and the first feature at a location of the first feature on the substrate, a first rotational value;
generating, for the second feature and using a geometric relationship defined between a second, different deposition flux vector and the second feature at a location of the second feature on the substrate, a second rotational value;
modifying the mask write file to generate a modified lithography mask write file comprising:
rotating the first and the second features about a respective first end of the first and second features and a respective second end of the first and second feature is rotated by the respective first and second rotational values.

8. The method of claim 7, wherein rotating the first and the second features comprises maintaining a minimum threshold overlap of the overlap region of the first and the second feature after rotating by the respective first and second rotational values.

9. The method of claim 7, wherein rotating the first and the second features comprises:
rotating the first feature about a first rotational direction; and
rotating the second feature about a second, different rotational direction.

10. The method of claim 7, wherein the first and the second features comprise an angle defined between vectors along respective lengths of the first and the second features, and wherein rotating the first and second features comprises
updating the angle between respective vectors defined along each respective length of the first and the second features, wherein the updated angle comprises one of an oblique angle and an acute angle.

11. The method of claim 10, wherein the write file comprises geometric and exposure time instructions for defining a pattern in a mask.

12. The method of claim 1, comprising performing lithography as directed by the modified write file.

13. The method of claim 2, wherein the circuit element is a quantum computing circuit element.

14. The method of claim 13, wherein the quantum computing circuit element comprises a Josephson junction.

15. The method of claim 2, comprising:
depositing a resist layer onto a substrate;
performing lithography on the resist layer as directed by the modified write file to fabricate a resist mask;
developing the resist mask;
performing a first deposition of a layer through the resist mask;
performing surface oxidation of the first deposited layer;
performing a second deposition through the resist mask; and
processing the resist mask and deposited layers to lift-off the resist mask and excess deposited material to form the circuit element.

16. The method of claim 2, comprising:
depositing one or more resist layers onto a substrate;
performing lithography on the one or more resist layers as directed by the modified write file to fabricate one or more resist masks, respectively;
developing the one or more resist masks;
performing one or more depositions of layers through the one or more resist masks to provide one or more deposited layers; and
processing the one or more resist masks and the one or more deposited layers to lift-off the one or more resist masks and excess deposited material to form the circuit element.

17. A system comprising:
a data processing apparatus;
a non-transitory memory storage in data communication with the data processing apparatus and storing instructions executable by the data processing apparatus and that upon such execution cause the data processing apparatus to perform operations comprising:
obtaining a write file comprising information characterizing a plurality of features arranged at a plurality of locations with respect to a surface of a substrate, each feature having a first end and a second end defined along a first feature direction of the feature;
generating for each of the plurality of locations and using a geometric relationship defined between a process vector of a process source of a fabrication system and the location of the feature on the substrate, a rotational value; and
modifying the write file to generate a modified write file comprising
for at least one feature of the plurality of features at a respective location with respect to the surface of the substrate, rotating the first feature direction of the feature about an axis normal to the surface of the substrate by the rotation value.

18. The system of claim 17, wherein the write file is a lithography mask write file, and wherein the geometric relationship is defined between a deposition flux vector of a deposition source of the fabrication system and the location of the feature on the substrate.

19. The system of claim 17, wherein generating the rotational value comprises:
obtaining a source-to-substrate distance for a substrate location of the feature on the substrate;
determining an angular difference between a component of the process vector and a feature vector along the first feature direction of the feature, the component of the process vector being parallel to the surface of the substrate at the location of the feature on the substrate; and
generating, using the angular difference and the source-to-substrate distance for the substrate location of the feature on the substrate, the rotational value.

20. One or more non-transitory computer storage media encoded with computer program instructions that when executed by one or more computers cause the one or more computers to perform operations comprising:
obtaining a write file comprising information characterizing a plurality of features arranged at a plurality of locations with respect to a surface of a substrate, each feature having a first end and a second end defined along a first feature direction of the feature;
generating for each of the plurality of locations and using a geometric relationship defined between a process vector of a process source of a fabrication system and the location of the feature on the substrate, a rotational value; and
modifying the write file to generate a modified write file comprising
for at least one feature of the plurality of features at a respective location with respect to the surface of the substrate, rotating the first feature direction of the feature about an axis normal to the surface of the substrate by the rotation value.
